(19) United States
(12) Patent Application Publication
(10) Pub. No.: US 2008/0290928 A1
(43) Pub. Date: Nov. 27, 2008

(54) SWITCHING CIRCUIT

(75) Inventors: Katsue Kawakyu, Kanagawa-ken (JP); Takayuki Teraguchi, Kanagawa-ken (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 12/123,819

(22) Filed: May 20, 2008

(30) Foreign Application Priority Data
May 24, 2007 (JP) 2007-137843

(51) Int. Cl. H03K 17/687

(52) U.S. Cl. 327/429

(57) ABSTRACT

A switching circuit is disclosed. The switching circuit is provided with first and second signal terminals, a control terminal, first and second resisters, and a field-effect transistor having a drain, a source, a gate and a back-gate. One end of the first resister is connected with the control terminal. The field-effect transistor is connected between the first and second signal terminals. The gate of the field-effect transistor is connected with the other end of the first resister. The back-gate of the field-effect transistor is connected with one end of the second resister. One of the source and drain of the first field-effect transistor is connected with the other end of the second resister.

### CROSS REFERENCE TO RELATED APPLICATION

The application is based upon and claims the benefit of priority from the prior Japanese Patent Application No. 2007-137843, filed on May 24, 2007, the entire contents of which are incorporated herein by reference.

### FIELD OF THE INVENTION

The present invention relates to a switching circuit having a field-effect transistor for switching a signal.

### DESCRIPTION OF THE BACKGROUND

A high frequency switching circuit is an important constituent part for a radio communication system such as a mobile communication or a LAN system. Lots of high frequency switching circuits are used in mobile phones, radio infra-structure facilities, satellite communication facilities or cable television facilities.

A high frequency switching circuit is disclosed in U.S. Pat. No. 6,094,088 or U.S. Pat. No. 6,882,829, for example.

The former patent shows a high frequency switching circuit having a pair of FETs (Field Effect Transistors) called as “Through FETs”, which are interposed in a signal lines between a pair of signal terminals and a common terminal connected to an antenna port. The through FETs function to switch two higher frequency input signals selectively. Further, in the high frequency switching circuit, a pair of FETs called as “Shunt FETs” are provided between the signal lines and a ground terminal. The high frequency switching circuit is provided with resisters. Ends of the resisters are respectively connected to the gates and back-gates of the Through FETs and Shunt FETs. Gates. The other ends of the resisters are respectively connected to the ground terminal. The resisters serve to suppress leakage of a high frequency signal.

The latter patent shows a high frequency switching circuit having a pair of Through FETs. The high frequency switching circuit is provided with resisters. Ends of the resisters are connected to the back-gates of the Through FETs. The other ends of the resisters are respectively connected to a ground terminal. The latter patent shows portions of signal lines and ground lines overlap with a space provided between the signal lines and ground lines. The high frequency switching circuit has parasitic capacitances in the overlapped portions respectively. By existence of the parasitic capacitances, leakage of higher frequency signals occurs. The signal leakage may cause lowering transmission and isolation characteristics of the high frequency switching circuit.

### SUMMARY OF THE INVENTION

An aspect of the present invention provides a switching circuit, which comprises first and second signal terminals to provide a signal from the first to the second signal terminal, a first control terminal to provide a first control signal, a first resister, one end of the first resister being connected with the first control terminal, a second resister, and a first field-effect transistor having a source, a drain, a gate and a back-gate to switch the signal, one of the source and drain of the first field-effect transistor being connected with the second signal terminal, the other of the source and drain of the first field-effect transistor being connected with the first signal terminal, the gate of the first field-effect transistor being connected with the other end of the first resister, the back-gate of the first field-effect transistor being connected with one end of the second resister, and one of the source and drain of the first field-effect transistor being connected with the other end of the second resister.

Another aspect of the present invention provides a switching circuit, which comprises first and second signal terminals to provide a signal from the first to the second signal terminal, a first control terminal to provide first control signal, a second control terminal to provide a second control signal, a ground terminal, a first resister, one end of the first resister being connected with the second control terminal, a second resister, and a first field-effect transistor having a source, a drain and a gate to switch the signal, one of the source and drain of the first field-effect transistor being connected with the second signal terminal, the other of the source and drain of the first field-effect transistor being connected with the first signal terminal, and the gate of the first field-effect transistor receiving the first control signal provided from the first control terminal, a second field-effect transistor having a source, a drain, a gate and a back-gate, one of the source and drain of the second field-effect transistor being connected with the first signal terminal, the other of the source and drain of the first field-effect transistor being connected with the ground terminal, the gate of the second field-effect transistor being connected with the other end of the first resister to receive the second control signal provided from the second control terminal, the back-gate of the second field-effect transistor being connected with one end of the second resister, and one of the source and drain of the second field-effect transistor being connected with the other end of the second resister.

Further another aspect of the present invention provides a switching circuit, which comprises a pair of first signal terminals to provide first and second signals respectively, a second signal terminal as a common terminal, the second signal terminal selectively receiving the first and second signals from the first signal terminals, a first control terminal to provide a first control signal, a second control terminal to provide a second control signal, a pair of first resisters, one end of each of the first resisters being connected with the first control terminal, a pair of second resisters, and a pair of first field-effect transistors, each of the first field-effect transistors having a source, a drain, a gate and a back-gate to switch the first and second signals, one of the source and drain of each of the first field-effect transistors being connected with the second signal terminal, the other of the source and drain of each of the first field-effect transistors being connected with the first signal terminal, the gate of each of the first field-effect transistors being connected with the other end of each of the first resisters, the back-gate of each of the first field-effect transistors being connected with one end of each of the second resisters, and one of the source and drain of each of the first field-effect transistor being connected with the other end of each of the second resisters.

### BRIEF DESCRIPTION OF THE DRAWINGS

FIG. 1 is a circuit diagram showing a configuration of a high frequency switching circuit according to a first embodiment of the present invention.

FIG. 2 is a circuit diagram showing a configuration of a high frequency switching circuit according to a second embodiment of the present invention.

FIG. 3 is a circuit diagram showing a configuration of a high frequency switching circuit according to a third embodiment of the present invention.

FIG. 4 is a schematic diagram showing a signal flow in an OFF state of a Through FET of the third embodiment.

FIG. 5 is a schematic diagram showing a signal flow in an OFF state of a Through FET according to a comparative example.

FIG. 6 is a circuit diagram showing a configuration of a high frequency switching circuit according to a fourth embodiment of the present invention.

### DETAILED DESCRIPTION OF THE INVENTION

Embodiments of the present invention will be explained with reference to the drawings. In the figures, the same parts are designated by the same reference numerals respectively.

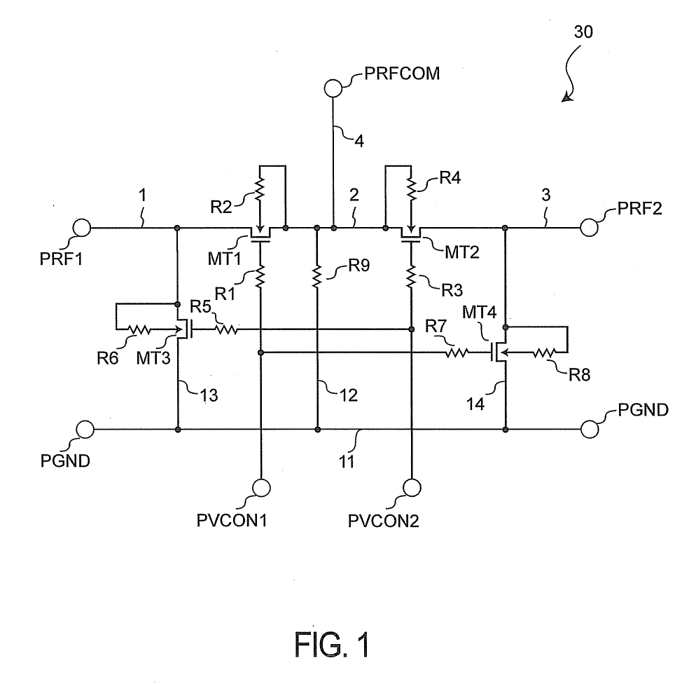

A first embodiment of the present invention will be explained with reference to FIG. 1. FIG. 1 is a circuit diagram showing a configuration of a high frequency switching circuit according to the first embodiment of the present invention. The high frequency switching circuit of the first embodiment is a SPDT (Single Pole Double Throw) type switch which is used as an antenna switch of a cellar phone, for example.

In FIG. 1, a high frequency switching circuit 30 is shown. The high frequency switching circuit 30 has N-channel MOS transistors MT1 to MT4 as insulated-gate field-effect transistors, resistors R1 to R9, a pair of RF (radio frequency) signal terminals PRF1, PRF2 as first high frequency signal terminals, a common RF terminal PRFCOM as a second high frequency signal terminal, control terminals PVCON1, PVCON2 as first and second control terminals respectively, and a ground terminal PGND.

The high frequency switching circuit 30 is further provided with signal lines 1-4 and ground lines 11-14.

The N-channel MOS transistors MT1 to MT4 are normally-off type MOS transistors, i.e. enhancement type (E-type) MOS transistors having a source, drain, gate and back-gate respectively.

The N-channel MOS transistors MT1, MT2 are Through FETs as first field-effect transistors. The N-channel MOS transistors MT3, MT4 are Shunt FETs as second field-effect transistors.

The common RF terminal PRFCOM is electrically connected to a port which is provided on an antenna side so as to output first and second high frequency signals, i.e. analog RF signals, to the antenna (not shown). The control terminals PVCON1, PVCON2 receive first and second control signals to control the N-channel MOS transistors MT1, MT2 respectively. The first and second high frequency signals are switched by the N-channel MOS transistors MT1, MT2 under control of the first and second control signals, so as to be provided alternatively from the RF signal terminals PRF1, PRF2 to the common RF terminal PRFCOM.

One end of the resistor R1 is connected to the control terminal PVCON1. The other end of the resistor R1 is connected to the gate of the N-channel MOS transistor MT1. One end of the resistor R2 is connected to the back-gate of the N-channel MOS transistor MT1. The other end of the resistor R2 is connected to one of the source and drain of the N-channel MOS transistor MT1, i.e. to one end of the N-channel MOS transistor MT1 on the side of the common RF terminal PRFCOM.

The one of the source and drain of the N-channel MOS transistor MT1 is connected to the common RF terminal PRFCOM. The other of the source and drain of the N-channel MOS transistor MT1 is connected to the RF terminal PRF1. The gate of the N-channel MOS transistor MT1 receives the first control signal output from the control terminal PVCON1 via the resistor R1.

The N-channel MOS transistor MT1 transmits the first high frequency signal received from the RF signal terminal PRF1 to the common RF terminal PRFCOM when the first control signal is at a “High” level.

One end of the resistor R3 is connected to the control terminal PVCON2. The other end of the resistor R3 is connected to the gate of the N-channel MOS transistor MT2. One end of the resistor 4 is connected to the back-gate of the N-channel MOS transistor MT2. The other end of the resistor R4 is connected to one of the source and drain of the N-channel MOS transistor MT2, i.e. to one end of the N-channel MOS transistor MT2 on the side of the common RF terminal PRFCOM. One end of the resistor R9 is connected to the common RF terminal PRFCOM. The other end of the resistor R9 is connected to the ground terminal PGND.

The other of the source and drain of the N-channel MOS transistor MT2 is connected with the RF signal terminals PRF2. The gate of the N-channel MOS transistor MT2 receives the second control signal output via the resistor R3 from the control terminal PVCON2. The N-channel MOS transistor MT2 transmits the second high frequency signal received from the RF signal terminal PRF2 to the common RF terminal PRFCOM when the second control signal is at a “High” level.

As described above, the other end of the resistor R2 is connected to the one of the source and drain of the N-channel MOS transistor MT1. Instead, the other end of the resistor R2 may be connected to the other of the source and drain of the N-channel MOS transistor MT1, i.e. to the side of the common RF terminal PRFCOM. The other end of the resistor R4 is connected to the other of the source and drain of the N-channel MOS transistor MT2. Instead, the other end of the resistor R4 may be connected to the one of the source and drain of the N-channel MOS transistor MT2, i.e. to the side of the RF terminal PRF2.

One end of the resistor R5 is connected to the control terminal PVCON2. The other end of the resistor R5 is connected to the gate of the N-channel MOS transistor MT3. One end of the resistor 6 is connected to the back-gate of the N-channel MOS transistor MT3. The other end of the resistor R6 is connected to one of the source and drain of the N-channel MOS transistor MT3.

The one of the source and drain of the N-channel MOS transistor MT3 is connected with the RF signal terminal PRF1. The other of the source and drain of the N-channel MOS transistor MT3 is connected with the ground terminal PGND. The gate of the N-channel MOS transistor MT3 receives the second control signal output from the control terminal PVCON2 via the resistor R5. The N-channel MOS transistor MT3 is in an ON state to set the RF signal terminal PRF1 at a lower voltage, i.e. a ground voltage, when the second control signal is at a “High” level.

One end of the resistor R7 is connected to the control terminal PVCON1. The other end of the resistor R7 is connected to the gate of the N-channel MOS transistor MT4. One end of the resistor R8 is connected to the back-gate of the N-channel MOS transistor MT4. The other end of the resistor R8 is connected to one of the source and drain of the N-channel MOS transistor MT4. One end of the resistor R9 is connected to a common RF terminal PRFCOM. The other end of the resistor R9 is connected to the ground terminal PGND.

The one of the source and drain of the N-channel MOS transistor MT4 is connected with the RF signal terminal PRF2. The other of the source and drain of the N-channel MOS transistor MT4 is connected with the ground terminal PGND of the lower voltage, i.e. the ground voltage. The gate of the N-channel MOS transistor MT4 receives the first control signal output from the control terminal PVCON1 via the resistor R7. The N-channel MOS transistor MT4 is in an ON state to set the RF signal terminal PRF2 at the lower voltage, i.e. the ground voltage, when the first control signal is at a “High” level.

As explained above, the other end of the resistor R6 is connected to the one of the source and drain of the N-channel MOS transistor MT3. Instead, the other end of the resistor R6 may be connected to the other of the source and drain of the N-channel MOS transistor MT3. The other end of the resistor R8 is connected to the one of the source and drain of the N-channel MOS transistor MT4. Instead, the other end of the resistor R8 may be connected to the other of the source and drain of the N-channel MOS transistor MT4.

The resistances of the resistor R1 to R8 are set at 5 to 100 kΩ, for example, and, preferably, at approximately 20 kΩ. The resistor R1 to R8 may be composed of a film such as a poly-silicon film formed on a field insulating film or an inter-layer insulating film which is provided on a semiconductor substrate, a metal nitride film, a metal carbide film or a diffusion resistor formed in a semiconductor substrate.

In the high frequency switching circuit 30 of the embodiment shown in FIG. 1, the back-gates of the N-channel MOS transistors MT1 to MT4 are connected to the one ends of the resistors R2, R4, R6 and R8 respectively. Each of the other ends of the resistors R2, R4, R6 and R8 is connected to the one of the source and drain of each of the N-channel MOS transistors MT1 to MT4.

Design of the high frequency switching circuit 30 may be easy to avoid making overlapped portions of the signal lines 1 to 4 and the ground lines 11 to 14. As a result, leakage of higher frequency signals may be suppressed which is caused due to existence of a parasitic capacitance. Thus, transmission and isolation characteristics of the high frequency signals may be sufficient.

In the above-mentioned embodiment, the N-channel MOS transistors MT1 to MT4 are employed. Instead, p-channel MOS transistors may be used.

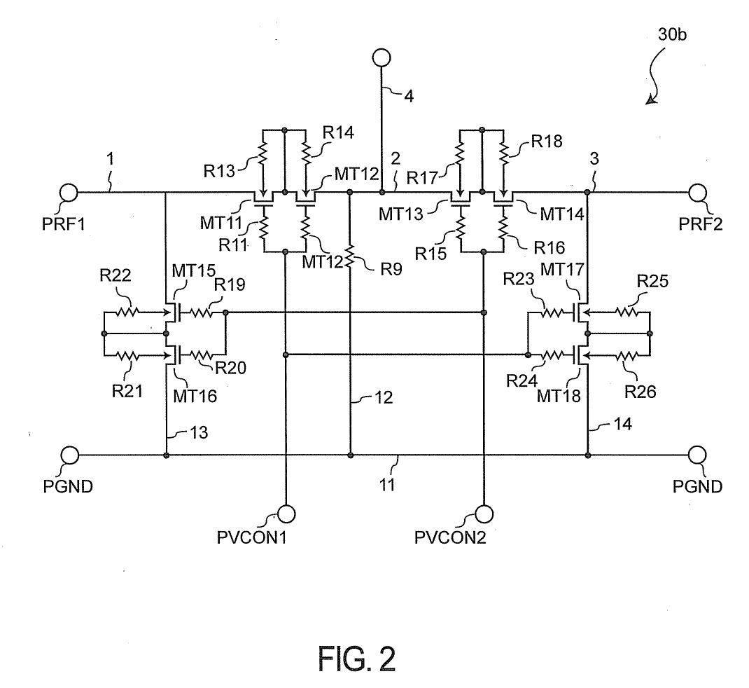

A second embodiment of the present invention will be explained with reference to FIG. 2. FIG. 2 is a circuit diagram showing a configuration of a high frequency switching circuit according to the first embodiment.

In FIG. 2, a high frequency switching circuit 30b is shown. As shown in FIG. 2, The high frequency switching circuit 30b has N-channel MOS transistors MT11 to MT18, resistor R9, resistors R11 to R26, a pair of RF (radio frequency) signal terminals PRF1, PRF2, a common RF terminal PRFCOM, control terminals PVCON1, PVCON2 and a ground terminal PGND.

The high frequency switching circuit 30b is further provided with signal lines 1-4 and ground lines 11-14. The high frequency switching circuit 30b is a SPDT (Single Pole Double Throw) type switch.

The N-channel MOS transistors MT11 to MT18 are normally-off type MOS transistors, i.e. an enhancement type (E-type) MOS transistors having a source, drain, gate and back-gate respectively.

The N-channel MOS transistors MT11 to MT14 are Through FETs as first field-effect transistors. The N-channel MOS transistors MT15 to MT18 are Shunt FETs as second field-effect transistors.

The control terminals PVCON1, PVCON2 receive first and second control signals to control the N-channel MOS transistors MT11 to MT14 respectively. First and second high frequency signals (RF signals) are switched by the N-channel MOS transistors MT11 to MT14 under control of the first and second control signals, so as to be provided alternatively from the RF signal terminals PRF1, PRF2 to the common RF terminal PRFCOM.

The N-channel MOS transistors MT11 and MT12 are connected in cascade (in series) with each other between the RF signal terminals PRF1 and the common RF terminal PRFCOM.

One end of the resistor R9 is connected to the common RF terminal PRFCOM. The other end of the resistor R9 is connected to the ground terminal PGND. One end of the resistor R11 is connected to the control terminal PVCON1. The other end of the resistor R11 is connected to the gate of the N-channel MOS transistor MT11.

One end of the resistor R12 is connected to the control terminal PVCON1. The other end of the resistor R12 is connected to the gate of the N-channel MOS transistor MT12.

One end of the resistor R13 is connected to the back-gate of the N-channel MOS transistor MT11. The other end of the resistor R13 is connected to one of the source and drain of the N-channel MOS transistor MT11, which is provided on the side of the N-channel MOS transistor MT12.

One end of the resistor R14 is connected to the back-gate of the N-channel MOS transistor MT12. The other end of the resistor R14 is connected to one of the source and drain of the N-channel MOS transistor MT12, which is provided on the side of the N-channel MOS transistor MT11.

The other of the source and drain of the N-channel MOS transistor MT11 is connected to the RF terminal PRF1. The one of the source and drain of the N-channel MOS transistor MT11 is connected to the one of the source and drain of the N-channel MOS transistor MT12. The gate of the N-channel MOS transistor MT11 receives a first control signal output from the control terminal PVCON1 via the resistor R11.

The other of the source and drain of the N-channel MOS transistor MT12 is connected to the common RF terminal PRFCOM.

The gate of the N-channel MOS transistor MT12 receives the first control signal output from the control terminal PVCON1 via the resistor R12.

The N-channel MOS transistor MT11 and MT12 are in an ON state to transmit the first high frequency signal received from the RF signal terminal PRF1 to the common RF terminal PRFCOM, when the first control signal is at a “High” level.

The N-channel MOS transistors MT13 and MT14 are connected in cascade (in series) with each other between the RF signal terminals PRF1 and the common RF terminal PRFCOM.

One end of the resistor R15 is connected to the control terminal PVCON2. The other end of the resistor R15 is connected to the gate of the N-channel MOS transistor MT13. One end of the resistor R16 is connected to the control terminal PVCON2. The other end of the resistor R16 is connected to the gate of the N-channel MOS transistor MT14. One end of the resistor R17 is connected to the back-gate of the N-channel MOS transistor MT13. The other end of the resistor R17 is connected to one of the source and drain of the N-channel MOS transistor MT13 which is one end of the N-channel MOS transistor MT13 provided on the side of the N-channel MOS transistor MT14. One end of the resistor R18 is connected to the back-gate of the N-channel MOS transistor MT14. The other end of the resistor R18 is connected to one of the source and drain of the N-channel MOS transistor MT14 which is one end of the N-channel MOS transistor MT13 provided on the side of the N-channel MOS transistor MT13. One end of the resistor R9 is connected to a common RF terminal PRFCOM. The other end of the resistor R9 is connected to the ground terminal PGND.

The other of the source and drain of the N-channel MOS transistor MT14 is connected to the RF terminal PRF2. The one of the source and drain of the N-channel MOS transistor MT14 is connected to the one of the source and drain of the N-channel MOS transistor MT13. The gate of the N-channel MOS transistor MT14 receives the second control signal output from the control terminal PVCON2 via the resistor R16.

The one of the source and drain of the N-channel MOS transistor MT13 is connected to the one of the source and drain of the N-channel MOS transistor MT14. The other of the source and drain of the N-channel MOS transistor MT13 is connected to the common RF terminal PRFCOM. The gate of the N-channel MOS transistor MT13 receives the second control signal output from the control terminal PVCON2 via the resistor R15.

The N-channel MOS transistor MT13 and MT14 are in an ON state to transmit the second high frequency signal received from the RF signal terminal PRF2 to the common RF terminal PRFCOM, when the second control signal is at a “High” level.

The N-channel MOS transistors MT15 and MT16 are connected in cascade (in series) with each other between the RF signal terminal PRF1 and the ground terminal PGND.

One end of the resistor R19 is connected to the control terminal PVCON2. The other end of the resistor R19 is connected to the gate of the N-channel MOS transistor MT15. One end of the resistor R20 is connected to the control terminal PVCON2. The other end of the resistor R20 is connected to the gate of the N-channel MOS transistor MT16. One end of the resistor R21 is connected to the back-gate of the N-channel MOS transistor MT16. The other end of the resistor R21 is connected to one of the source and drain of the N-channel MOS transistor MT16. One end of the resistor R22 is connected to the back-gate of the N-channel MOS transistor MT15. The other end of the resistor R22 is connected to one of the source and drain of the N-channel MOS transistor MT15.

The other of the source and drain of the N-channel MOS transistor MT15 is connected to the RF terminal PRF1. The one of the source and drain of the N-channel MOS transistor MT15 is connected to the one of the source and drain of the N-channel MOS transistor MT16. The gate of the N-channel MOS transistor MT15 receives the second control signal output from the control terminal PVCON2 via the resistor R19. The other of the source and drain of the N-channel MOS transistor MT16 is connected to the ground terminal PGND. The gate of the N-channel MOS transistor MT16 receives the second control signal output from the control terminal PVCON2 via the resistor R20.

The N-channel MOS transistor MT15 and MT16 are in an ON state to connect the RF signal terminal PRF1 to the ground terminal PGND to set the RF signal terminal PRF1 at a lower voltage (ground voltage).

The N-channel MOS transistors MT17 and MT18 are connected in cascade (in series) with each other between the RF signal terminal PRF1 and the ground terminal PGND.

One end of the resistor R23 is connected to the control terminal PVCON1. The other end of the resistor R23 is connected to the gate of the N-channel MOS transistor MT17. One end of the resistor R24 is connected to the control terminal PVCON1. The other end of the resistor R24 is connected to the gate of the N-channel MOS transistor MT18. One end of the resistor R25 is connected to the back-gate of the N-channel MOS transistor MT17. The other end of the resistor R25 is connected to one of the source and drain of the N-channel MOS transistor MT18. One end of the resistor R26 is connected to the back-gate of the N-channel MOS transistor MT18. The other end of the resistor R26 is connected to one of the source and drain of the N-channel MOS transistor MT18.

The other of the source and drain of the N-channel MOS transistor MT17 is connected to the RF terminal PRF2. The gate of the N-channel MOS transistor MT17 receives the first control signal output from the control terminal PVCON1 via the resistor R23.

The other of the source and drain of the N-channel MOS transistor MT18 is connected to the ground terminal PGND. The gate of the N-channel MOS transistor MT18 receives the first control signal output from the control terminal PVCON1 via the resistor R24.

The N-channel MOS transistor MT17 and MT18 are in an ON state to connect the RF signal terminal PRF2 to the ground terminal PGND electrically so as to set the RF signal terminal PRF2 at the lower voltage (ground voltage), when the first control signal is at a “High” level.

The resistances of the resistor R11 to R26 are set at 5 to 100 kΩ, for example, and, preferably, at approximately 20 kΩ. The resistor R11 to R26 may be composed of a film such as a poly-silicon film formed on a field insulating film or an inter-layer insulating film which is provided on a semiconductor substrate, a metal nitride film, a metal carbide film or a diffusion resistor formed in a semiconductor substrate.

In the high frequency switching circuit 30b of the embodiment shown in FIG. 2, the back-gates of the N-channel MOS transistors MT11 and MT12 are connected to the one ends of the resistors R13, R14 respectively. Each of the other ends of the resistors R13, R14 is connected to the one of the source and drain of each of the N-channel MOS transistor MT11 or to the one of the source and drain of each of the N-channel MOS transistor MT12.

Similarly, each of the resistors R15 to R26, which are connected to the back-gates of the N-channel MOS transistors MT13 to MT18, is connected to the one of the source and drain of each of the N-channel MOS transistor MT13 to 18.

Design of the high frequency switching circuit 30b may be easy to avoid making overlapped portions of the signal lines 1 to 4 and the ground lines 11 to 14.

As a result, leakage of higher frequency signals may be suppressed which is caused due to existence of a parasitic capacitance. Thus, transmission and isolation characteristics of the high frequency signals may be sufficient.

The above-mentioned embodiment is provided with the N-channel MOS transistors MT11 to MT18 each two of which are connected in cascade with each other to constitute the Through and Shunt FETs.

Each of the Through and Shunt FETs may be composed of a “n” set of N-channel MOS transistors wherein the “n” is an integer equal to three or more. The “n” set of N-channel MOS transistors may be connected with resisters respectively. In this case, one end of each of resisters may be connected to the back-gates of N-channel MOS transistors, and the other end of each of resisters may be connected to each of common connection portions of the N-channel MOS transistors.

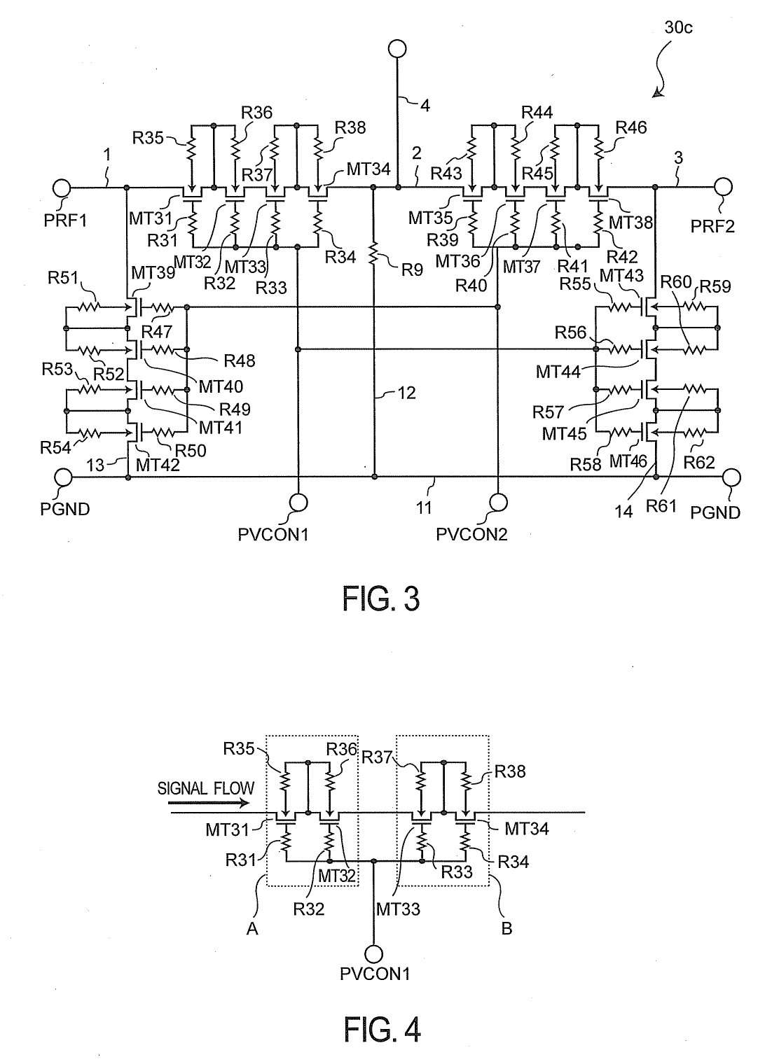

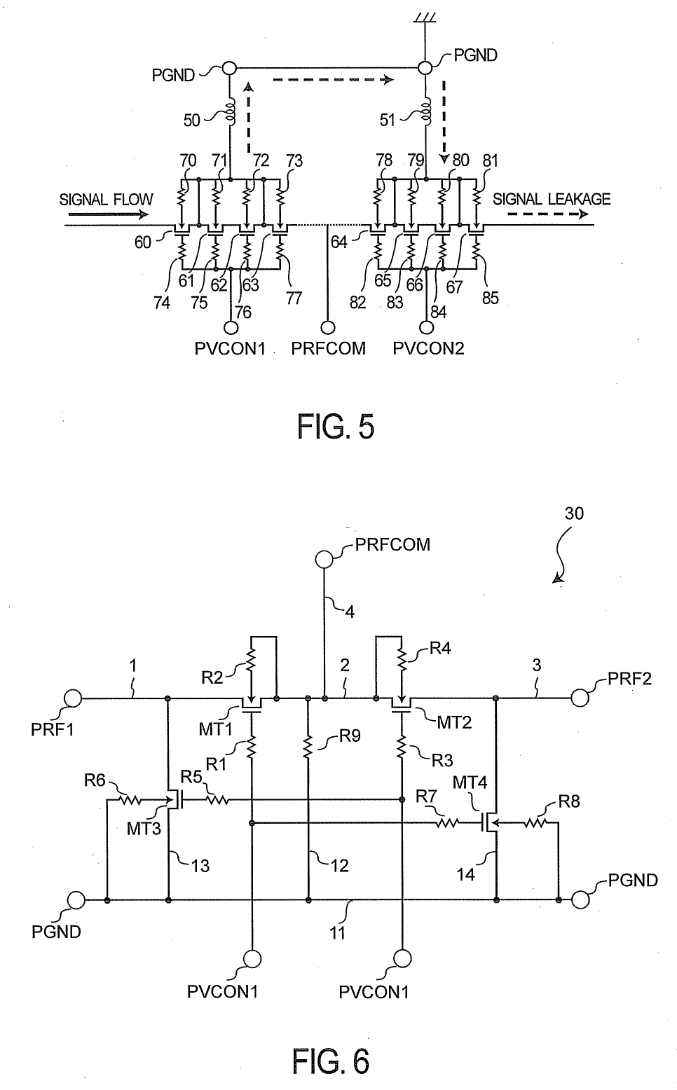

A third embodiment of the present invention will be explained with reference to FIGS. 3 to 5. FIG. 3 is a circuit diagram showing a configuration of a high frequency switching circuit according to the third embodiment. FIG. 4 is a schematic diagram showing a signal flow in an OFF state of a Through FET of the third embodiment. FIG. 5 is a schematic diagram showing a signal flow in an OFF state of a Through FET according to a comparative example.

In FIG. 3, a high frequency switching circuit 30c is shown. As shown in FIG. 2, the high frequency switching circuit 30c has N-channel MOS transistors MT31 to MT46, resistor R9, resistors R31 to R62, a pair of RF (radio frequency) signal terminals PRF1, PRF2, a common RF terminal PRFCOM, control terminals PVCON1, PVCON2 and a ground terminal PGND.

The high frequency switching circuit 30c is further provided with signal lines 1-4 and ground lines 11-14. The high frequency switching circuit 30c is a SPDT (Single Pole Double Throw) type switch.

The N-channel MOS transistors MT31 to MT46 are normally-off type MOS transistors, i.e. enhancement type (E-type) MOS transistors having a source, drain, gate and back-gate respectively.

The N-channel MOS transistors MT31 to MT38 are Through FETs as first field-effect transistors. The N-channel MOS transistors MT39 to MT46 are Shunt FETs as second field-effect transistors.

The control terminals PVCON1, PVCON2 receive first and second control signals to control the N-channel MOS transistors MT31 to MT38 respectively. First and second high frequency signals (RF signals) are switched by the N-channel MOS transistors MT31 to MT38 under control of the first and second control signals, so as to be provided alternatively from the RF signal terminals PRF1, PRF2 to the common RF terminal PRFCOM.

The N-channel MOS transistors MT31 to MT34 are connected in cascade (in series) with each other between the RF signal terminals PRF1 and the common RF signal terminal PRFCOM.

One end of the resistor R9 is connected to the common RF terminal PRFCOM. The other end of the resistor R9 is connected to the ground terminal PGND.

One end of the resistor R31 is connected to the control terminal PVCON1. The other end of the resistor R31 is connected to the gate of the N-channel MOS transistor MT31. One end of the resistor R32 is connected to the control terminal PVCON1. The other end of the resistor R32 is connected to the gate of the N-channel MOS transistor MT32. One end of the resistor R33 is connected to the control terminal PVCON1. The other end of the resistor R33 is connected to the gate of the N-channel MOS transistor MT33. One end of the resistor R34 is connected to the control terminal PVCON1. The other end of the resistor R33 is connected to the gate of the N-channel MOS transistor MT34.

One end of the resistor R35 is connected to the back-gate of the N-channel MOS transistor MT31. The other end of the resistor R35 is connected to one of the source and drain of the N-channel MOS transistor MT31, which is provided on the side of the N-channel MOS transistor MT32.

One end of the resistor R36 is connected to the back-gate of the N-channel MOS transistor MT32. The other end of the resistor R36 is connected to one of the source and drain of the N-channel MOS transistor MT32, which is provided on the side of the N-channel MOS transistor MT31.

One end of the resistor R37 is connected to the back-gate of the N-channel MOS transistor MT33. The other end of the resistor R37 is connected to one of the source and drain of the N-channel MOS transistor MT33, which is provided on the side of the N-channel MOS transistor MT34.

One end of the resistor R38 is connected to the back-gate of the N-channel MOS transistor MT34. The other end of the resistor R34 is connected to one of the source and drain of the N-channel MOS transistor MT34, which is provided on the side of the N-channel MOS transistor MT33.

The other of the source and drain of the N-channel MOS transistor MT31 is connected to the RF terminal PRF1. The one of the source and drain of the N-channel MOS transistor MT31 is connected to the one of the source and drain of the N-channel MOS transistor MT32. The gate of the N-channel MOS transistor MT31 receives the first control signal output from the control terminal PVCON1 via the resistor R31.

The other of the source and drain of the N-channel MOS transistor MT32 is connected to the N-channel MOS transistor MT33.

The gate of the N-channel MOS transistor MT32 receives the first control signal output from the control terminal PVCON1 via the resistor R32.

The one of the source and drain of the N-channel MOS transistor MT33 is connected to the one of the source and drain of the N-channel MOS transistor MT33. The gate of the N-channel MOS transistor MT33 receives the first control signal output from the control terminal PVCON1 via the resistor R33.

The other of the source and drain of the N-channel MOS transistor MT34 is connected to the common RF terminal PRFCOM. The gate of the N-channel MOS transistor MT34 receives the first control signal output from the control terminal PVCON1 via the resistor R34.

The N-channel MOS transistors MT31 to MT34 are in an ON state to transmit the first high frequency signal received from the RF signal terminal PRF1 to the common RF terminal PRFCOM, when the first control signal is at a “High” level.

The N-channel MOS transistors MT35 to MT38 are connected in cascade (in series) with each other between the RF signal terminals PRF1 and the common RF terminal PRFCOM.

One end of the resistor R39 is connected to the control terminal PVCON2. The other end of the resistor R39 is connected to the gate of the N-channel MOS transistor MT35.

One end of the resistor R40 is connected to the control terminal PVCON2. The other end of the resistor R40 is connected to the gate of the N-channel MOS transistor MT36. One end of the resistor R41 is connected to the control terminal PVCON2. The other end of the resistor R41 is connected to the gate of the N-channel MOS transistor MT37. One end of the resistor R42 is connected to the control terminal PVCON2. The other end of the resistor R42 is connected to the gate of the N-channel MOS transistor MT38.

One end of the resistor R43 is connected to the back-gate of the N-channel MOS transistor MT35. The other end of the resistor R43 is connected to one of the source and drain of the N-channel MOS transistor MT35, which is provided on the side of the N-channel MOS transistor MT36.

One end of the resistor R44 is connected to the back-gate of the N-channel MOS transistor MT36. The other end of the resistor R44 is connected to one of the source and drain of the N-channel MOS transistor MT36, which is provided on the side of the N-channel MOS transistor MT35.

One end of the resistor R45 is connected to the back-gate of the N-channel MOS transistor MT37. The other end of the resistor R45 is connected to one of the source and drain of the N-channel MOS transistor MT37, which is provided on the side of the N-channel MOS transistor MT38.

One end of the resistor R46 is connected to the back-gate of the N-channel MOS transistor MT38. The other end of the resistor R46 is connected to one of the source and drain of the N-channel MOS transistor MT38, which is provided on the side of the N-channel MOS transistor MT37.

The other of the source and drain of the N-channel MOS transistor MT35 is connected to the common RF terminal PRFCOM. The gate of the N-channel MOS transistor MT35 receives the second control signal output from the control terminal PVCON2 via the resistor R39.

The one of the source and drain of the N-channel MOS transistor MT36 is connected to the one of the source and drain of the N-channel MOS transistor MT35. The other of the source and drain of the N-channel MOS transistor MT36 is connected to the N-channel MOS transistor MT37. The gate of the N-channel MOS transistor MT36 receives the second control signal output from the control terminal PVCON2 via the resistor R40.

The one of the source and drain of the N-channel MOS transistor MT37 is connected to the one of the source and drain of the N-channel MOS transistor MT36. The other of the source and drain of the N-channel MOS transistor MT37 is connected to the one of the source and drain of the N-channel MOS transistor MT38. The gate of the N-channel MOS transistor MT37 receives the second control signal output from the control terminal PVCON2 via the resistor R41.

The other of the source and drain of the N-channel MOS transistor MT38 is connected to the RF terminal PRF2. The gate of the N-channel MOS transistor MT38 receives the second control signal output from the control terminal PVCON2 via the resistor R42.

The N-channel MOS transistors MT35 to MT38 are in an ON state to transmit the second high frequency signal received from the RF signal terminal PRF2 to the common RF terminal PRFCOM, when the second control signal is at a “High” level.

The N-channel MOS transistors MT39 to MT42 are connected in cascade (in series) with each other between the RF signal terminals PRF1 and the ground terminal PGND.

One end of the resistor R47 is connected to the control terminal PVCON2. The other end of the resistor R47 is connected to the gate of the N-channel MOS transistor MT39. One end of the resistor R48 is connected to the control terminal PVCON2. The other end of the resistor R48 is connected to the gate of the N-channel MOS transistor MT40. One end of the resistor R49 is connected to the control terminal PVCON2. The other end of the resistor R49 is connected to the gate of the N-channel MOS transistor MT41. One end of the resistor R50 is connected to the control terminal PVCON2. The other end of the resistor R50 is connected to the gate of the N-channel MOS transistor MT42.

One end of the resistor R51 is connected to the back-gate of the N-channel MOS transistor MT39. The other end of the resistor R51 is connected to one of the source and drain of the N-channel MOS transistor MT39.

One end of the resistor R52 is connected to the back-gate of the N-channel MOS transistor MT40. The other end of the resistor R52 is connected to one of the source and drain of the N-channel MOS transistor MT40.

One end of the resistor R53 is connected to the back-gate of the N-channel MOS transistor MT41. The other end of the resistor R53 is connected to one of the source and drain of the N-channel MOS transistor MT41.

One end of the resistor R54 is connected to the back-gate of the N-channel MOS transistor MT42. The other end of the resistor R54 is connected to one of the source and drain of the N-channel MOS transistor MT42.

The one of the source and drain of the N-channel MOS transistor MT39 is connected to the one of the source and drain of the N-channel MOS transistor MT40. The other of the source and drain of the N-channel MOS transistor MT39 is connected to the RF terminal PRF1. The gate of the N-channel MOS transistor MT39 receives the second control signal output from the control terminal PVCON2 via the resistor R47.

The other of the source and drain of the N-channel MOS transistor MT40 is connected to the N-channel MOS transistor MT41. The gate of the N-channel MOS transistor MT40 receives the second control signal output from the control terminal PVCON2 via the resistor R48.

The one of the source and drain of the N-channel MOS transistor MT41 is connected to the one of the source and drain of the N-channel MOS transistor MT42. The other of the source and drain of the N-channel MOS transistor MT41 is connected to the other of the source and drain of the N-channel MOS transistor MT40. The gate of the N-channel MOS transistor MT41 receives the second control signal output from the control terminal PVCON2 via the resistor R49.

The other of the source and drain of the N-channel MOS transistor MT42 is connected to the ground terminal PGND. The gate of the N-channel MOS transistor MT42 receives the second control signal output from the control terminal PVCON2 via the resistor R50.

The N-channel MOS transistors MT39 to MT42 are in an ON state to connect the RF signal terminal PRF2 to the ground terminal PGND electrically so as to set the RF signal terminal PRF2 at a lower voltage (ground voltage), when the second control signal is at a “High” level.

The N-channel MOS transistors MT43 to MT46 are connected in cascade (in series) with each other between the RF signal terminals PRF2 and the ground terminal PGND.

One end of the resistor R55 is connected to the control terminal PVCON1. The other end of the resistor R55 is connected to the gate of the N-channel MOS transistor MT43. One end of the resistor R56 is connected to the control terminal PVCON1. The other end of the resistor R56 is connected to the gate of the N-channel MOS transistor MT44. One end of the resistor R57 is connected to the control terminal PVCON1. The other end of the resistor R57 is connected to the gate of the N-channel MOS transistor MT45. One end of the resistor R58 is connected to the control terminal PVCON1. The other end of the resistor R58 is connected to the gate of the N-channel MOS transistor MT46.

One end of the resistor R59 is connected to the back-gate of the N-channel MOS transistor MT43. The other end of the resistor R59 is connected to one of the source and drain of the N-channel MOS transistor MT43. One end of the resistor R60 is connected to the back-gate of the N-channel MOS transistor MT44. The other end of the resistor R60 is connected to one of the source and drain of the N-channel MOS transistor MT44. One end of the resistor R61 is connected to the back-gate of the N-channel MOS transistor MT45. The other end of the resistor R61 is connected to one of the source and drain of the N-channel MOS transistor MT45. One end of the resistor R62 is connected to the back-gate of the N-channel MOS transistor MT46. The other end of the resistor R62 is connected to one of the source and drain of the N-channel MOS transistor MT46.

The one of the source and drain of the N-channel MOS transistor MT43 is connected to the one of the source and drain of the N-channel MOS transistor MT44. The other of the source and drain of the N-channel MOS transistor MT43 is connected to the RF terminal PRF2. The gate of the N-channel MOS transistor MT43 receives the first control signal output from the control terminal PVCON1 via the resistor R55.

The other of the source and drain of the N-channel MOS transistor MT44 is connected to the other of the source and drain of the N-channel MOS transistor MT45. The gate of the N-channel MOS transistor MT44 receives the first control signal output from the control terminal PVCON1 via the resistor R56.

The one of the source and drain of the N-channel MOS transistor MT45 is connected to the one of the source and drain of the N-channel MOS transistor MT46. The gate of the N-channel MOS transistor MT45 receives the first control signal output from the control terminal PVCON1 via the resistor R57.

The other of the source and drain of the N-channel MOS transistor MT46 is connected to the ground terminal PGND. The gate of the N-channel MOS transistor MT46 receives the first control signal output from the control terminal PVCON1 via the resistor R58.

The N-channel MOS transistors MT43 to MT46 are in an ON state to connected the RF signal terminal PRF2 to the ground terminal PGND electrically so as to set at the lower voltage (ground voltage), when the first control signal is at a “High” level.

In the high frequency switching circuit 30c, the first and second high frequency signals, which are analog RF signals, are switched by the N-channel MOS transistors MT31 to MT34 and MT35 to MT38 under control of the first and second control signals respectively. As a result, the first and second high frequency signals are provided alternatively from the RF signal terminals PRF1, PRF2 to the common RF terminal PRFCOM which is electrically connected to a port disposed on an antenna side.

The resistances of the resistor R31 to R62 are set at 5 to 100 kΩ, for example, and, preferably, at approximately 20 kΩ. The resistor R31 to R62 may be composed of a film such as a poly-silicon film formed on a field insulating film or an inter-layer insulating film which is provided on a semiconductor substrate, a metal nitride film, a metal carbide film or a diffusion resistor formed in a semiconductor substrate.

According to the high frequency switching circuit 30c of the embodiment shown in FIG. 3, each of the back-gates of the N-channel MOS transistors MT31, MT32 is connected to each of the one ends of the set of the resistors R35 and R36. Each of the other ends of the set of the resistors R35 and R36 is connected to the one of the source and drain of each of the N-channel MOS transistor MT31, or to the one of the source and drain of each of the N-channel MOS transistor MT32.

Similarly, each of the other sets of the resistors R37 and R38, R43 and R44, R45 and R46, R51 and R52, R53 and R54, R55 and R56, and R57 and R58 respectively connected to the back-gates of the N-channel MOS transistors MT33 to MT46 is connected to the one of the source and drain of each of the N-channel MOS transistor MT33 to 46.

Thus, design of the high frequency switching circuit 30c may be easy to avoid making overlapped portions of the signal lines 1 to 4 and the ground lines 11 to 14.

A signal flow of the high frequency switching circuit 30c will be described with reference to FIG. 4. FIG. 4 denotes a circuit diagram representatively which is equivalent to the left top portion of the high frequency switching circuit 30c shown in FIG. 3. FIG. 4 shows a signal flow which is obtained in an OFF state of the N-channel MOS transistors MT31 to MT46 of FIG. 3.

In FIG. 4, two blocks A, B are shown. The block A includes the N-channel MOS transistors MT31, MT32 as the Through FETs and the resisters 31, 32, 35 and 36. The block B includes the N-channel MOS transistors MT33, MT34 as the Through FETs and the resisters 33, 34, 37 and 38. The back-gates of the N-channel MOS transistors MT31, MT32 of the block A and the back-gates of the N-channel MOS transistors MT33, MT34 of the block B are electrically isolated.

Thus, even if a high frequency signal is input to the block A when the N-channel MOS transistors MT31 to MT34 are in an OFF state, the leakage of the high frequency signal through the back-gates of the N-channel MOS transistors MT31 to MT34 is suppressed. As a result, deterioration of isolation may be suppressed to arise between the high frequency signal terminals. Similar operations are respectively performed in the other similar portions of FIG. 3, i.e. the portion including the N-channel MOS transistors MT35 to MT38 as the Through FETs and the resisters R43 to R46, the portion including the N-channel MOS transistors MT39 to MT42 as the Shunt FETs and the resisters R51 to R54, and the portion including the N-channel MOS transistors MT43 to MT46 as the Shunt FETs and the resisters R55 to R58.

FIG. 5 denotes a circuit diagram of a comparative example which corresponds to the top portion of the high frequency switching circuit 30c shown in FIG. 3. FIG. 5 shows a signal flow in an OFF state of Through FETs according to the comparative example. In FIG. 5, the circuit block shown on the left side includes N-channel MOS transistors MT60 to MT63 as Through FETs and the resisters R70 to R77 having high resistances. In FIG. 5, the circuit block shown on the right side includes N-channel MOS transistors MT64 to MT67 as Through FETs and the resisters R78 to R85 having high resistances. These circuit blocks have the similar interconnections as those of the corresponding top portion of FIG. 3. But, the circuit blocks of FIG. 5 are different from the corresponding top portion of FIG. 3 in that any of the back-gates of the N-channel MOS transistors MT60 to MT63 are connected with each other, and in that any of the back-gates of the N-channel MOS transistors MT64 to MT67 are connected with each other.

The common end of the resisters R70 to R77 is connected to a ground terminal PGND via an interconnection 50 formed by wire-bonding. The common end of the resisters R78 to R81 is connected to a ground terminal PGND via an interconnection 51 formed by wire-bonding. When the impedances of the back-gates are large due to the inductance components of the interconnections 50, 51, etc., leakage of high frequency signals arise through the resisters R70 to R73 and R78 to R81 connected with the back-gate. As a result, deterioration of isolation may arise between the high frequency signal terminals.

According to the embodiment, each two of the N-channel MOS transistors constituting the Through FETs and Shunt FETs MT31 to MT34 are connected in cascade (in series) with each other to form each of the sets of N-channel MOS transistors. Each two of the sets of the N-channel MOS transistors are connected in cascade (in series) with each other to form each of the portions for transmitting and shunting of the high frequency signals.

Instead, “m” sets, each of which has two N-channel MOS transistors connected in cascade (in series) with each other, may be connected in cascade (in series) with each other, wherein the “m” is an integer equal to three or more. Each of the sets may be composed of three N-channel MOS transistors which are connected in cascade (in series) with each other.

A fourth embodiment of the present invention will be explained with reference to FIG. 6. FIG. 6 is a circuit diagram showing a configuration of a high frequency switching circuit according to the fourth embodiment of the present invention.

The high frequency switching circuit 30d shown in FIG. 6 differs from the embodiment of FIG. 1 in that one end of a resister R6 is connected with the back-gate of a N-channel MOS transistor MT3 and in that the other end of a resister R6 is connected to a ground terminal PGND. Further, the high frequency switching circuit 30d of FIG. 6 differs from the embodiment of FIG. 1 in that one end of a resister R8 is connected with the back-gate of a N-channel MOS transistor MT4 and in that the other end of a resister R8 is connected to a ground terminal PGND.

The high frequency switching circuit 30d of the embodiment may be easy to avoid making overlapped portions of the signal lines 1 to 4 and the ground lines 11 to 14. As a result, leakage of higher frequency signals may be suppressed which is caused due to existence of a parasitic capacitance. Thus, transmission and isolation characteristics of the high frequency signals may be sufficient.

In the afore-mentioned embodiments, the N-channel MOS transistors are employed in the high frequency switching circuits as insulated-gate field-effect transistors. The MOS transistors may be replaced with field-effect transistors of GaAs or junction transistors.

The afore-mentioned embodiments are a SPDT (Single Pole Double Throw) type switch. The invention may be applied to a SPnT type or an mPnT type switch. The SPnT type switch has one pole and “n” throws, where the “n” is an integer equal to three or more. The mPnT type switch has “m” poles and “n” throws, where the “m” is an integer equal to two or more and where the “n” is an integer equal to two or more.

The fundamental structure of the high frequency switching circuits may be constituted by at least one Through FET.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A switching circuit comprising:
first and second signal terminals to provide a signal from the first to the second signal terminal;
a first control terminal to provide a first control signal;
a first resister, one end of the first resister being connected with the first control terminal;
a second resister; and
a first field-effect transistor having a source, a drain, a gate and a back-gate to switch the signal, one of the source and drain of the first field-effect transistor being connected with the second signal terminal, the other of the source and drain of the first field-effect transistor being connected with the first signal terminal, the gate of the first field-effect transistor being connected with the other end of the first resister, the back-gate of the first field-effect transistor being connected with one end of the second resister, and one of the source and drain of the first field-effect transistor being connected with the other end of the second resister.

2. The switching circuit according to claim 1, wherein the other end of the second resister is connected with the second signal terminal.

3. The switching circuit according to claim 1, further comprising:
a second control terminal to provide a second control signal;
a ground terminal;
a third resister, one end of the third resister being connected with the second control terminal;
a fourth resister; and
a second field-effect transistor having a source, a drain, a gate and a back-gate, one of the source and drain of the second field-effect transistor being connected with the first signal terminal, the other of the source and drain of the second field-effect transistor being connected with the ground terminal, the gate of the first field-effect transistor being connected with the other end of the third resister, the back-gate of the second field-effect transistor being connected with one end of the fourth resister, and one of the source and drain of the second field-effect transistor being connected with the other end of the fourth resister.

4. The switching circuit according to claim 3, wherein the other end of the fourth resister is connected with the ground terminal.

5. The switching circuit according to claim 1, further comprising:
a third field-effect transistor having a source, a drain, a gate and a back-gate;
a fifth resister, one end of the fifth resister being connected with the first control terminal; and
a sixth resister,
wherein one of the source and drain of the third field-effect transistor is connected with the one of the source and drain of the first field-effect transistor, the other of the source and drain of the third field-effect transistor is connected with the second signal terminal, the gate of the third field-effect transistor is connected with the other end of the fifth resister, the back-gate of the third field-effect transistor is connected with one end of the sixth resister, and one of the source and drain of the third field-effect transistor is connected with the other end of the sixth resister.

6. The switching circuit according to claim 3, further comprising:
a fourth field-effect transistor having a source, a drain, a gate and a back-gate;
a seventh resister, one end of the seventh resister being connected with the first control terminal; and
a eighth resister,
wherein one of the source and drain of the fourth field-effect transistor is connected with the one of the source and drain of the second field-effect transistor, the other of the source and drain of the fourth field-effect transistor is connected with the first signal terminal, the gate of the fourth field-effect transistor is connected with the other end of the seventh resister, the back-gate of the fourth field-effect transistor is connected with one end of the eighth resister, and one of the source and drain of the fourth field-effect transistor is connected with the other end of the eighth resister.

7. The switching circuit according to claim 5, further comprising:
a fifth field-effect transistor having a source, a drain, a gate and a back-gate;
a ninth resister, one end of the ninth resister being connected with the first control terminal; and
a tenth resister;
wherein one of the source and drain of the fifth field-effect transistor is connected with the one of the source and drain of the first field-effect transistor, the other of the source and drain of the fifth field-effect transistor is connected with the second signal terminal, the gate of the fifth field-effect transistor is connected with the other end of the ninth resister, the back-gate of the fifth field-effect transistor is connected with one end of the tenth resister, one of the source and drain of the fifth field-effect transistor is connected with the other end of the tenth resister, and the other end of the tenth resister and the other end of the sixth resister are isolated electrically.

8. The switching circuit according to claim 7, further comprising:
a sixth field-effect transistor having a source, a drain, a gate and a back-gate;
an eleventh resister, one end of the eleventh resister being connected with the second control terminal; and
a twelfth resister;
wherein one of the source and drain of the sixth field-effect transistor is connected with the one of the source and drain of the fourth field-effect transistor, the other of the source and drain of the sixth field-effect transistor is connected with the first signal terminal, the gate of the sixth field-effect transistor is connected with the other end of the eleventh resister, the back-gate of the sixth field-effect transistor is connected with one end of the twelfth resister, one of the source and drain of the sixth field-effect transistor is connected with the other end of the twelfth resister, and the other end of the twelfth resister and the other end of the eighth resister are isolated electrically.

9. A switching circuit comprising:
first and second high frequency signal terminals to provide a signal from the first to the second signal terminal;
a first control terminal to provide first control signal;
a second control terminal to provide a second control signal;
a ground terminal;
a first resister, one end of the first resister being connected with the second control terminal;
a second resister; and
a first field-effect transistor having a source, a drain and a gate to switch the signal, one of the source and drain of the first field-effect transistor being connected with the second signal terminal, the other of the source and drain of the first field-effect transistor being connected with the first signal terminal, and the gate of the first field-effect transistor receiving the first control signal provided from the first control terminal;
a second field-effect transistor having a source, a drain, a gate and a back-gate, one of the source and drain of the second field-effect transistor being connected with the first signal terminal, the other of the source and drain of the first field-effect transistor being connected with the ground terminal, the gate of the second field-effect transistor being connected with the other end of the first resister to receive the second control signal provided from the second control terminal, the back-gate of the second field-effect transistor being connected with one end of the second resister, and one of the source and drain of the second field-effect transistor being connected with the other end of the second resister.

10. The switching circuit according to claim 9, further comprising:
a third field-effect transistor having a source, a drain, a gate and a back-gate;
a third resister, one end of the third resister being connected with the second control terminal; and
a fourth resister,
wherein one of the source and drain of the third field-effect transistor is connected with the one of the source and drain of the second field-effect transistor, the other of the source and drain of the third field-effect transistor is connected with the first signal terminal, the gate of the third field-effect transistor is connected with the other end of the third resister, the back-gate of the third field-effect transistor is connected with one end of the fourth resister, and one of the source and drain of the third field-effect transistor is connected with the other end of the fourth resister.

11. A switching circuit comprising:
a pair of first signal terminals to provide first and second signals respectively;
a second signal terminal as a common terminal, the second signal terminal selectively receiving the first and second signals from the first signal terminals;
a first control terminal to provide a first control signal;
a second control terminal to provide a second control signal;
a pair of first resisters, one end of each of the first resisters being connected with the first control terminal;
a pair of second resisters; and
a pair of first field-effect transistors, each of the first field-effect transistors having a source, a drain, a gate and a back-gate, one of the source and drain of each of the first field-effect transistors being connected with the second signal terminal, the other of the source and drain of each of the first field-effect transistors being connected with each of the first signal terminals, the gate of each of the first field-effect transistors being connected with the other end of each of the first resisters, the back-gate of each of the first field-effect transistors being connected with one end of each of the second resisters, and one of the source and drain of each of the first field-effect transistor being connected with the other end of each of the second resisters.

12. The switching circuit according to claim 11, wherein the other end of each of the second resisters is connected with the second signal terminal.

13. The switching circuit according to claim 11, further comprising:
a ground terminal;
a pair of third resisters, one end of one of the third resisters being connected with the second control terminal, and one end of the other of the third resisters being connected with the first control terminal;
a pair of fourth resisters; and
a pair of second field-effect transistors, each of the second field-effect transistors having a source, a drain, a gate and a back-gate, one of the source and drain of each of the second field-effect transistors being connected with the second signal terminal, the other of the source and drain of each of the second field-effect transistor being connected with the ground terminal, the gate of each of the second field-effect transistors being connected with the other end of each of the third resisters, the back-gate of each of the second field-effect transistors being connected with one end of each of the fourth resisters, and one of the source and drain of each of the second field-effect transistor being connected with the other end of each of the fourth resisters.

14. The switching circuit according to claim 13, wherein the one end of each of the fourth resisters is connected with the ground terminal.

15. The switching circuit according to claim 11, further comprising:
a pair of third field-effect transistors, each of the third field-effect transistors having a source, a drain, a gate and a back-gate;
a pair of fifth resisters, one end of one of the fifth resisters being connected with the first control terminal, and one end of the other of the fifth resisters being connected with the second control terminal; and
a pair of sixth resisters,
wherein one of the source and drain of each of the third field-effect transistors is connected with the one of the source and drain of each of the first field-effect transistors, the other of the source and drain of each of the third field-effect transistors is connected with the second signal terminal, the gate of each of the third field-effect transistors is connected with the other end of each of the fifth resisters, the back-gate of each of the third field-effect transistors is connected with one end of each of the sixth resisters, and one of the source and drain of each of the third field-effect transistors is connected with the other end of each of the sixth resisters.

16. The switching circuit according to claim 13, further comprising:
a pair of fourth field-effect transistors, each of the fourth field-effect transistors having a source, a drain, a gate and a back-gate;
a pair of seventh resisters, one end of one of the seventh resisters being connected with the second control terminal and one end of the other of the seventh resisters being connected with the first control terminal; and
a pair of eighth resisters,
wherein one of the source and drain of each of the fourth field-effect transistors is connected with the one of the source and drain of each of the second field-effect transistors, the other of the source and drain of each of the fourth field-effect transistors is connected with the first signal terminal, the gate of each of the fourth field-effect transistors is connected with the other end of each of the seventh resisters, the back-gate of each of the fourth field-effect transistors is connected with one end of each of the eighth resisters, and one of the source and drain of each of the fourth field-effect transistors is connected with the other end of each of the eighth resisters.

17. The switching circuit according to claim 15, further comprising:
a pair of fifth field-effect transistors having a source, a drain, a gate and a back-gate;
a pair of ninth resisters, one end of one of the ninth resisters being connected with the first control terminal, and one end of the other of the ninth resisters being connected with the second control terminal; and
a pair of tenth resisters;
wherein one of the source and drain of each of the fifth field-effect transistors is connected with the other of the source and drain of each of the third field-effect transistor, the other of the source and drain of each of the fifth field-effect transistors is connected with the second signal terminal, the gate of each of the fifth field-effect transistor is connected with the other end of each of the ninth resisters, the back-gate of each of the fifth field-effect transistors is connected with one end of each of the tenth resisters, one of the source and drain of each of the fifth field-effect transistors is connected with the other end of each of the tenth resisters, and the other end of each of the tenth resisters and the other end of each of the sixth resister are isolated electrically.

18. The switching circuit according to claim 17, further comprising:
A pair of sixth field-effect transistors, each of the sixth field-effect transistors having a source, a drain, a gate and a back-gate;
a pair of eleventh resisters, one end of each of the eleventh resisters being connected with the first control terminal; and
a pair of twelfth resisters;
wherein one of the source and drain of each of the sixth field-effect transistors is connected with the one of the source and drain of each of the fifth field-effect transistors, the other of the source and drain of each of the sixth field-effect transistors is connected with the second signal terminal, the gate of each of the sixth field-effect transistors is connected with the other end of each of the eleventh resisters, the back-gate of each of the sixth field-effect transistors is connected with one end of each of the twelfth resisters, one of the source and drain of each of the sixth field-effect transistors is connected with the other end of each of the twelfth resisters, and the other end of each of the twelfth resisters and the other end of each of the eighth resisters are isolated electrically.

19. The switching circuit according to claim 11, wherein the first field-effect transistors are a normally-off type.
